(19) United States
(12) Patent Application Publication
(10) Pub. No.: US 2006/0057472 A1
(43) Pub. Date: Mar. 16, 2006

(54) Method for making chrome photo mask

(76) Inventor: Robert Chin Fu Tsai, Hsinchu (TW)

Correspondence Address: SMITH, GAMBRELL & RUSSELL, LLP, 1850 M STREET, N.W., SUITE 800, WASHINGTON, DC, 20036, US

(21) Appl. No.: 10/940,714

(22) Filed: Sep. 15, 2004

(51) Int. Cl. C23F 1/00; C25D 5/02; C23F 3/00; B44C 1/22; G03F 1/00

(52) U.S. Cl. 430/5; 216/79; 205/118; 205/122

(57) ABSTRACT

A method for making a chrome photo-mask is disclosed. A photo-mask blank is activated with activator on its upper surface for electroless chrome plating Next, the activated photo-mask blank is then immersed in the electroless chrome plating solution for being coated with a thin chrome layer. The electroless chrome plating process will continue until a desired thickness is formed. Preferably, an electro-plating process is employed after the growth of an initial electroless chrome layer. Then, the photo-mask blank with the chrome layer is subject to oxidation for forming an antireflection layer on the chrome layer. After the antireflective layer is successively formed, a resist film is formed on the antireflective layer. The resist film is then patterned in accordance with the predetermined pattern. Next, the antireflective layer and the chromium layer are dry-etched or wet-etched through openings in the patterned resist film. The resist film is subsequently stripped to form the desired photo-mask.

### BACKGROUND OF THE INVENTION

1. Field of the Invention

The present invention generally relates to a photo-mask, and more particularly to method for making a large area chrome photo-mask.

2. Description of the Related Art

Photo-lithographic processes involving the use of photo-masks are employed in the micro-fabrication of high-density semiconductor integrated circuits such as LSI and VLSI chips, colour filters, liquid-crystal displays, and magnetic heads.

Photo-masks used for micro-fabrication are produced from a photo-mask blank composed of a transparent substrate such as quartz glass or aluminosilicate glass and a light-shielding film, typically in the form of a chromium film, deposited thereon by a sputtering or vacuum evaporation technique. The photo-mask is created by forming a specific pattern in the light-shielding film of the photo-mask blank.

The photo-mask blanks from which photo-masks are formed generally have two and three-layer structures. The two-layer structure photo-mask blanks include a light-shielding film, typically in the form of a chromium film, deposited on a synthetic quartz substrate by sputtering or vacuum evaporation, and an antireflective film deposited on the surface of the chromium film for preventing the exposure light reflected by the silicon wafer from being reflected again. The three-layer structure photo-mask blanks are arrived at by forming an additional antireflective film on the substrate side.

An important requirement of photo-masks is that the substrate be flat to assure accurate transfer of the pattern. Yet, no matter how flat a substrate is used, forming a light-shielding chromium base film on the substrate tends to exacerbate the surface state, especially in the two-layer structure, because the light-shielding film is characterized by growth of large grains on the substrate surface. Current trends in the micro-fabrication industry are towards increased circuit pattern density on the silicon wafers or glass substrates. As the circuit pattern density is increased, the permissible defect size and density on the photo-mask necessarily decrease. This decrease translates into fewer and smaller permissible defects in the photo-mask blank, a substrate having an opaque film thereon, from which the photo-mask is formed.

A primary source of defects in photo-mask blanks is the blank manufacturing process. Conventional photo-mask blanks include two or more different masking layers on the transparent substrate. A light blocking chrome or chrome-based layer and a chrome oxide antireflective layer are the basic masking layers. Additional layers such as further antireflective layers, etch rate enhancing layers and adhesion promoting layers are also used.

Typically, each masking layer is coated individually in separate coating operations. This is done, for example, by sputtering a chrome layer on an uncoated substrate in a sputter chamber, then removing the chrome coated substrate from the chamber, altering the conditions in the chamber to create a chrome oxide sputtering atmosphere and then subjecting the chrome coated substrate to the new conditions. This type of process has some disadvantages. Between coating the different layers, the coating surface is susceptible to contamination. The contamination may be in the form of solid particulates created by mechanical removal and return of the substrate from and to the chamber, or solid residue, particles or dust remaining in the chamber from the previous sputtering conditions. Moreover, the contamination may also be gaseous should there by any backstreaming of the vacuum pumping system between passes through the sputtering chamber.

Both forms of contamination reduce the adhesion at the coating interfaces in the final blank. Any adhesion loss, whether local or uniform, at any interface in the blank is a potential defect site in the final photo-mask. The rigorous processing steps of exposure, development, etching, stripping and numerous cleaning cycles, to which a blank is subjected in the manufacture of a photo-mask, enhance the likelihood that a given adhesion loss in a blank will generate a defect site in the photo-mask produced therefrom.

Another disadvantage of coating the masking layers in separate sputtering operations is the abrupt compositional interfaces between the layers. Such abrupt interfaces suffer from brittleness and poor adhesion. In addition, the layers of different composition etch at different rates during formation of the circuit pattern in the film thereby creating defects such as antireflective layer overhang, and rough line edge profile, in the etched pattern.

Efforts to eliminate the foregoing defects have focused on adding other layers to the opaque film and changing the composition of the light-blocking, chrome based layer and/or the antireflective layer. Many approaches to eliminating blank defects are disclosed, for example, in U.S. Pat. No. 4,530,891 to Nagarekawa et al., U.S. Pat. No. 4,563,407 to Matsui et al., U.S. Pat. No. 4,720,422 Shinkai et al., and U.S. Pat. No. 6,727,027 Tsukamoto et al.

However, the cost for the above patents is very high due to the sputtering processes involved. In additions, the uniformity is difficult to control, and the processes therein are still vulnerable to particle defects.

Accordingly, there exists a need for a novel method for making a photo-mask which solves the above mentioned problems and disadvantages.

### SUMMARY OF THE INVENTION

It is an object of the present invention to provide a method for making a photo-mask by much cheaper and better controlled plating process.

It is another object of the present invention to provide a method for making a photo-mask which has a significantly improved surface flatness to accept high-sensitivity detection for the defect inspection and circuit pattern inspection.

In order to achieve the objects mentioned hereinabove, a photo-mask blank is coated with resists on its lower surface and edges. Then, the photo-mask blank coated with resists is immersed in the electroless chrome plating activator for surface activation. Alternatively, by using the spin cup design, the photo-mask blank is spinning and sprayed with chrome activator on the upper surface thereof with N₂ gas blowing from the lower surface of the photo-mask blank. Next, the activated photo-mask blank is then immersed in the electroless chrome plating solution for being coated with a thin chrome layer. The electroless chrome plating process will continue until a desired thickness is formed. The chrome layer can also be electro-plated to the desired thickness with good uniformity. Then, the photo-mask blank with the chrome layer is subject to oxidation for forming an antireflection layer on the chrome layer.

After the antireflective layer is successively formed, a resist film is formed on the antireflective layer. The resist film is then patterned in accordance with the predetermined pattern. Next, the antireflective layer and the chromium layer are dry-etched or wet-etched through openings in the patterned resist film. The resist film is subsequently stripped to form the desired photo-mask.

The present invention provides a novel method for making photo-mask by much cheaper and better controlled plating process. The photo-mask in accordance with the present invention has a significantly improved surface flatness to accept high-sensitivity detection for the defect inspection and circuit pattern inspection and capable of accurately forming a desired micropattern. The resulting photo-mask can accommodate higher integration in semiconductor integrated circuits and related devices.

### BRIEF DESCRIPTION OF THE DRAWINGS

Other objects, advantages, and novel features of the invention will become more apparent from the following detailed description in conjunction with the accompanying drawing.

FIG. 1 is a sectional view of a photo-mask blank according to one embodiment of the invention.

FIG. 2 is a sectional view of a photo-mask blank coated with resists.

FIG. 3 is a sectional view of a photo-mask blank with a chrome layer.

FIG. 4 is a sectional view of a photo-mask blank with an antireflection layer on the chrome layer.

FIG. 5 is a series of schematic sectional views illustrating a photo-mask manufacturing method such as may be used in connection with the invention. FIG. 5A shows a photomask blank on which a resist film has been formed, FIG. 5B shows the blank after the resist film has been patterned, FIG. 5C shows the blank after dry etching or wet etching, and FIG. 5D shows the completed photo-mask after the resist film has been removed.

FIG. 6 is a flow chart illustrating the method for making chrome photo-mask in accordance with the present invention.

### DESCRIPTION OF THE PREFERRED EMBODIMENT

To physically realize the sputtering processes for making photo-mask is either difficult to control the uniformity or high cost, the present invention develops a novel method for making photo-mask by much cheaper and better controlled plating process. The advantages of the present invention are much significant for large area chrome photo mask.

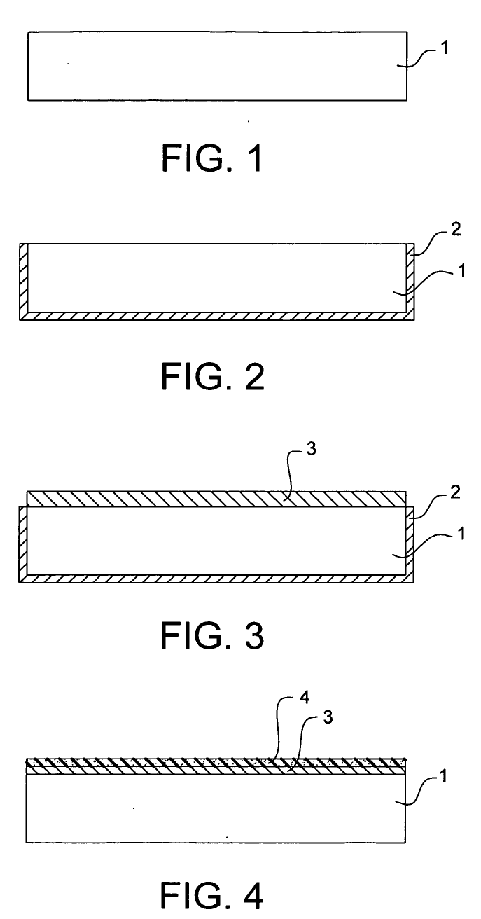

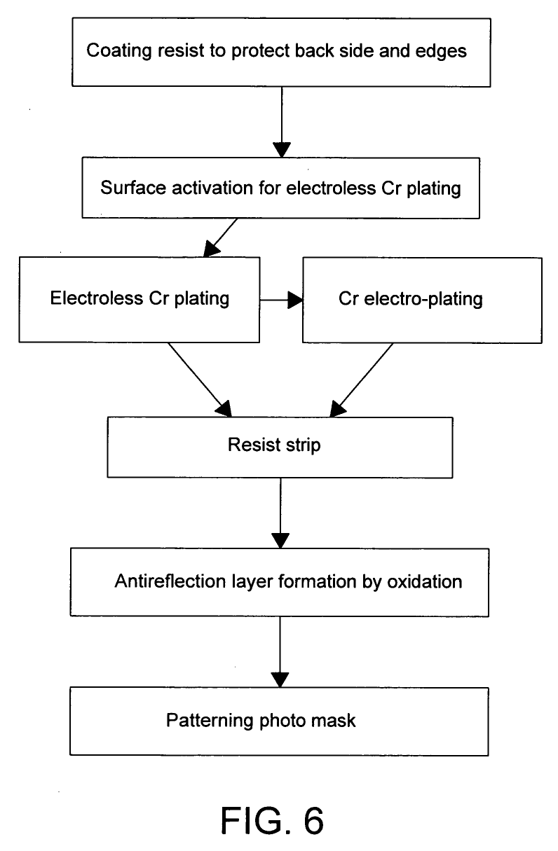

Referring to FIGS. 1 and 6, the photo-mask blank 1 of the invention includes a transparent substrate by which exposure light is transmitted. The photo-mask blank 1 is made of any desired material that is transparent to the exposure light, for example, preferably quartz, aluminosilicate glass, calcium fluoride or magnesium fluoride and soda lime glass. Referring to FIG. 2, the photo-mask blank 1 is coated with resists 2 on its lower surface and edges. Then, the photo-mask blank 1 coated with resists 2 is soft baked to enhance the adhesion between the photo-mask blank 1 and resist 2, and to drive off all solvent therein. The thickness uniformity of the resist 2 is not critical in this process. Then, the photo-mask blank 1 coated with resists 2 is immersed in the electroless chrome plating activator for surface activation. Suitable electroless chrome plating activators are alkalline solution of chromium chloride and 2-propanol.

Another embodiment of the present invention prevents the lower surface and edges of the photo-mask blank 1 from deposition of chrome without using resists 2. According to this embodiment, by using the spin cup design, the photo-mask blank 1 is spinning and sprayed with chrome activator on the upper surface of the photo-mask blank 1 with N₂ gas blowing from the lower surface of the photo-mask blank 1, thereby preventing the lower surface and edges of the photo-mask blank 1 from deposition of chrome.

Next, the activated photo-mask blank 1 is then immersed in the electroless chrome plating solution for being coated with a thin chrome layer 3. The electroless chrome plating process will continue until a desired thickness of about 1000 Å is formed. Alternately, an electroplating process can be employed after the growth of an initial electroless chrome layer to a desired thickness.

After the desired thickness of chrome layer 3 is formed on the photo-mask blank 1, the photo-resists 2 are stripped from the photo-mask blank 1 and the photo-mask blank 1 is properly rinsed. Then, the photo-mask blank 1 with the chrome layer 3 is subject to oxidation in a controlled environment for forming an antireflection layer 4 on the chrome layer 3. For the antireflective layer 4, the chromium materials containing at least one of oxygen, nitrogen and carbon are suitable. Examples include chromium oxide, chromium nitride, chromium oxynitride, chromium oxycarbide, and chromium oxide nitride carbide, with the chromium oxycarbide and chromium oxide nitride carbide being preferred. The chrome oxide with proper thickness for the antireflective layer 4 is a useful medium to create negative interference with the reflected laser beam from the bottom side of the photo-mask during the pattern writing. Preferably, the antireflective film is ¼ λ of wavelength of the laser beam for patterning writing, for example, 10 to 100 nm thick, especially 20 to 40 nm thick.

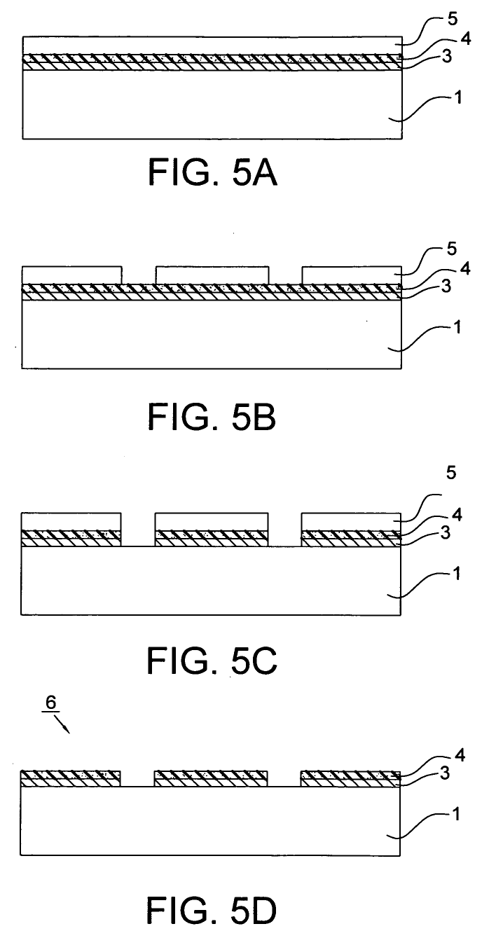

After the antireflective layer 4 is successively formed, a resist film 5 is formed on the antireflective layer 4 (FIG. 5A). The resist film 5 is then patterned in accordance with the predetermined pattern (FIG. 5B). Next, the antireflective layer 4 and the chrome layer 3 are dry-etched or wet-etched through openings in the patterned resist film 5 (FIG. 5C). The resist film 5 is subsequently stripped to form the desired photo-mask 6 (FIG. 5D). In this process, application of the resist film, patterning (exposure and development), dry or wet etching, and removal of the resist film may be carried out by known methods.

There has been described a photo-mask 6 having a significantly improved surface flatness to accept high-sensitivity detection for the defect inspection and circuit pattern inspection and capable of accurately forming a desired micropattern. The resulting photo-mask 6 can accommodate higher integration in semiconductor integrated circuits and related devices. Accordingly, the present invention provides a novel method for making photo-mask by much cheaper and better controlled plating process. The advantages of the present invention are much significant for large area chrome photo mask.

While the foregoing description and drawings represent the embodiments of the present invention, it will be understood that various additions, modifications and substitutions may be made therein without departing from the spirit and scope of the principles of the present invention as defined in the accompanying claims. One skilled in the art will appreciate that the invention may be used with many modifications of form, structure, arrangement, proportions, materials, elements, and components. The presently disclosed embodiments are therefore to be considered in all respects as illustrative and not restrictive, the scope of the invention being indicated by the appended claims and their legal equivalents, and not limited to the foregoing description.

What is claimed is:

1. A method for making a chrome photo-mask comprising the steps of:
providing a photo-mask blank;
coating a resist on the lower surface and edges of the photo-mask blank;
immersing the photo-mask blank coated with photo-resists in an electroless chrome plating activator for surface activation;
electroless chrome plating the photo-mask blank to form a chrome layer thereon;
stripping the resist from the photo-mask blank;
oxidizing the a chrome layer to form an antireflection layer; and
patterning the antireflection layer and the chrome layer to form a photo-mask.

2. The method according to claim 1, further comprising the step of soft bakeing the photo-mask blank coated with resist to enhance the adhesion therebetween and to drive off all solvent therein.

3. The method according to claim 1, further comprising the step of electro-plating chrome on the photo-mask blank after the growth of an initial electroless chrome layer.

4. The method according to claim 1, wherein the antireflection layer and the chrome layer are patterned by dry-etching to form a photo-mask.

5. The method according to claim 1, wherein the antireflection layer and the chrome layer are patterned by wet-etching to form a photo-mask.

6. A method for making a chrome photo-mask comprising the steps of:
providing a photo-mask blank;
activating the photo-mask blank with an electroless chrome plating activator for surface activation;
electroless chrome plating the photo-mask blank to form a chrome layer thereon;
stripping the resist from the photo-mask blank;
oxidizing the a chrome layer to form an antireflection layer; and
patterning the antireflection layer and the chrome layer to form a photo-mask.

7. The method according to claim 6, further comprising the step of electro-plating chrome on the photo-mask blank after the growth of an initial electroless chrome layer.

8. The method according to claim 6, wherein the antireflection layer and the chrome layer are patterned by dry-etching to form a photo-mask.

9. The method according to claim 6, wherein the antireflection layer and the chrome layer are patterned by wet-etching to form a photo-mask.

10. The method according to claim 6, wherein the photo-mask blank is activated by spinning and sprayed with chrome activator on the upper surface thereof with N₂ gas blowing from the lower surface of the photo-mask blank

11. A method for making a chrome photo-mask comprising the steps of:
activating a photo-mask blank with an electroless chrome plating activator;
electroless chrome plating the photo-mask blank to form a chrome layer thereon;
electro-plating chrome on the photo-mask blank after the growth of an initial electroless chrome layer;
stripping the resist from the photo-mask blank;
oxidizing the a chrome layer to form an antireflection layer; and
patterning the antireflection layer and the chrome layer to form a photo-mask.

12. The method according to claim 11, wherein the antireflection layer and the chrome layer are patterned by dry-etching to form a photo-mask.

13. The method according to claim 11, wherein the antireflection layer and the chrome layer are patterned by wet-etching to form a photo-mask.
